(19) United States
(12) Patent Application Publication
(10) Pub. No.: US 2026/0341367 A1
(43) Pub. Date: Oct. 29, 2026

(54) Self-Erasing Semiconductor Memory Device

(71) Applicant: Sandisk Technologies, Inc., Milpitas, CA (US)

(72) Inventors: Gilad Marko, Ra'anana (IL); Shay Benisty, Beer Sheva (IL)

(73) Assignee: Sandisk Technologies, Inc., Milpitas, CA (US)

(21) Appl. No.: 19/188,754

(22) Filed: Apr. 24, 2025

(51) Int. Cl. G11C 16/22; G11C 16/16; G11C 16/32

(52) U.S. Cl. CPC G11C 16/22; G11C 16/16; G11C 16/32

(57) ABSTRACT

A semiconductor memory device includes a memory die having stored thereon a set of data. A memory controller is electrically connected to the memory die and configured to detect disconnection of the semiconductor memory device from a host device, determine an amount of time that the semiconductor memory device has been disconnected from the host device, and in response to the amount of time being greater than or equal to a timeout value, prevent the set of data stored on the memory die from being accessed or modified. The memory controller may prevent or at least substantially reduce the risk of data stored on the memory die from being compromised or leaked to an unknown entity.

### BACKGROUND

The present disclosure generally relates to semiconductor memory devices and, more particularly, to a self-erasing semiconductor memory device.

A semiconductor memory device may include a plurality of semiconductor memory dies and a controller packaged together to store and transmit data. In some instances, semiconductor memory devices are transportable (e.g., storage drives, NAND flash drives) or included in vehicles, manned or unmanned. Additionally, the data stored on the memory device may be sensitive and/or confidential. Accordingly, it may be undesirable for that data to be retrieved, accessed, and/or modified by an unauthorized user or otherwise compromised. Therefore, there is a need to provide a semiconductor memory device configured to prevent data stored thereon from be accessed or modified in response to an external event that may cause the data to be compromised.

### SUMMARY

In one embodiment there is a semiconductor memory device including a memory die having stored thereon a set of data, and a memory controller electrically connected to the memory die, the memory controller configured to: detect disconnection of the semiconductor memory device from a host device, determine an amount of time that the semiconductor memory device has been disconnected from the host device, and in response to determining that the amount of time is greater than or equal to a timeout value, prevent the set of data stored on the memory die from being accessed or modified.

In some embodiments, the memory controller is further configured to, in response to detecting the removal of the semiconductor memory device from the host device, initiate a timer to track the amount of time that the semiconductor memory device has been disconnected from the host device. In some embodiments, the memory controller is further configured to, determine if the semiconductor memory device is connected to the host device, and reset and pause the timer tracking the amount of time that the semiconductor memory device has been disconnected from the host device. In some embodiments, the memory controller is further configured to, when preventing the set of data stored on the memory die from being accessed or modified, prevent any read or write commands to the memory die.

In some embodiments, the memory controller is further configured to, when preventing the set of data stored on the memory die from being accessed or modified, erase encryption keys associated with the set of data stored on the memory die. In some embodiments, the memory controller is further configured to, when preventing the set of data stored on the memory die from being accessed or modified, delete a logical to physical (L2P) table associated with the set of data stored on the memory die. In some embodiments, the memory controller is further configured to, when preventing the set of data stored on the memory die from being accessed or modified, transmit an erase command to the memory die to cause the set of data stored thereon to be erased.

In some embodiments, the memory controller is further configured to, when preventing the set of data stored on the memory die from being accessed or modified, execute one or more of: erasure of encryption keys associated with the set of data stored on the memory die, deletion of a logical to physical (L2P) table associated with the set of data stored on the memory die, and transmission of an erase command to the memory die to cause the set of data stored thereon to be erased. In some embodiments, the memory controller is further configured to execute the erasure of the encryption keys, deletion of the L2P table and transmission of the erase command in a sequence according to predetermined criteria of the set of data stored on the memory die.

In some embodiments, the memory controller is configured to enable a user to set the predetermined criteria. In some embodiments, the memory controller is further configured to: detect that the semiconductor memory device is connected to an external device other than the host device, and prevent the set of data stored on the memory die from being accessed or modified. In some embodiments, the memory die is a NAND flash memory die.

In another embodiment there is a method of preventing access or modification of data stored on a semiconductor memory device, the method including at a memory controller electrically connected to a memory die: detecting disconnection of the semiconductor memory device from a host device, determining an amount of time that the semiconductor memory device has been disconnected from the host device, and in response to determining that the amount of time is greater than or equal to a timeout value, preventing a set of data stored on the memory die from being accessed or modified.

In some embodiments, the method further includes, at the memory controller, in response to detecting the removal of the semiconductor memory device from the host device, initiating a timer to track the amount of time that the semiconductor memory device has been disconnected from the host device. In some embodiments, the method further includes, at the memory controller, determining if the semiconductor memory device is connected to the host device, and resetting and pausing the timer tracking the amount of time that the semiconductor memory device has been disconnected from the host device. In some embodiments, preventing the set of data stored on the memory die from being accessed or modified includes erasing, via the memory controller, encryption keys associated with the set of data stored on the memory die. In some embodiments, preventing the set of data stored on the memory die from being accessed or modified includes deleting, via the memory controller, a logical to physical (L2P) table associated with the set of data stored on the memory die.

In some embodiments, preventing the set of data stored on the memory die from being accessed or modified includes, via the memory controller, transmitting an erase command to the memory die to cause the set of data stored thereon to be erased. In some embodiments, preventing the set of data stored on the memory die from being accessed or modified includes executing, via the memory controller, one or more of: erasing encryption keys associated with the set of data stored on the memory die, deleting a logical to physical (L2P) table associated with the set of data stored on the memory die, and transmitting an erase command to the memory die to cause the set of data stored thereon to be erased.

In another embodiment there is a semiconductor memory device including a storage means for storing a set of data, and a storage controller means for controlling access to the storage means, the storage controller means configured to, detect disconnection of the semiconductor memory device from a host device, determine an amount of time that the semiconductor memory device has been disconnected from the host device, and in response to determining that the amount of time is greater than or equal to a timeout value, prevent the set of data stored on the storage means from being accessed or modified.

### BRIEF DESCRIPTION OF THE DRAWINGS

The foregoing summary, as well as the following detailed description, will be better understood when read in conjunction with the appended drawings. For the purpose of illustrating the present disclosure, there are shown in the drawings embodiments, which are presently preferred, wherein like reference numerals indicate like elements throughout. It should be noted, however, that aspects of the present disclosure can be embodied in different forms and thus should not be construed as being limited to the illustrated embodiments set forth herein. The elements illustrated in the accompanying drawings are not necessarily drawn to scale, but rather, may have been exaggerated to highlight the important features of the subject matter therein. Furthermore, the drawings may have been simplified by omitting elements that are not necessarily needed for the understanding of the disclosed embodiments.

In the drawings:

FIG. 1 is a block diagram illustrating a semiconductor memory system in accordance with an exemplary embodiment of the present disclosure; and

FIG. 2 is a flowchart illustrating a method of automatically erasing data on a semiconductor memory device in accordance with an exemplary embodiment of the present disclosure.

### DETAILED DESCRIPTION

The present subject matter will now be described more fully hereinafter with reference to the accompanying Figures, in which representative embodiments are shown. The present subject matter can, however, be embodied in different forms and should not be construed as limited to the embodiments set forth herein. Rather, these embodiments are provided to describe and enable one of skill in the art.

Numerous details are described herein in order to provide a thorough understanding of the example embodiments illustrated in the accompanying drawings. However, some embodiments may be practiced without any of the specific details, and the scope of the claims is only limited by those features and aspects specifically recited in the claims. Furthermore, well-known methods, components, and circuits have not be described in exhaustive detail so as not to unnecessarily obscure pertinent aspects of the embodiments described herein.

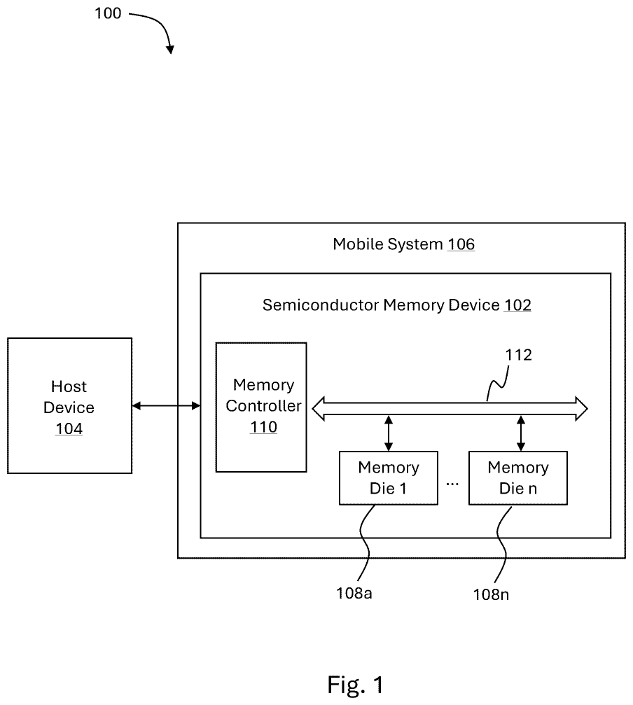

Referring to FIG. 1, there is shown a semiconductor memory system, generally designated 100, in accordance with an exemplary embodiment of the present disclosure. The system 100 may include a semiconductor memory device 102 for storing data and a host device 104 configured to connect to the semiconductor memory device 102. Connection of the memory device 102 and host device 104 may include physically and/or communicatively coupling the memory device 102 and host device 104 to one another as discussed in more detail below. The host device 104 may be a computing device such as, but not limited to, a desktop computer, laptop computer, tablet, smartphone, and/or server system. In some embodiments, a connection between the memory device 102 and host device 104 may be established via a physical connection (e.g., a universal serial bus (USB), data transfer cable) and/or a wireless connection (e.g., via a local area network (LAN), wide area network (WAN), Bluetooth™, Wi-Fi, WPA3). In some embodiments, the semiconductor memory device 102 and host device 104 are configured to communicate with one another over a secure wireless communications network.

The semiconductor memory device 102 may be included in a semiconductor device package, such as, but not limited to, a system-in-package (SiP), a memory card (e.g., a secure digital (SD) card or a MultiMediaCard (MMC)). In some embodiments, the semiconductor memory device 102 is a solid state drive (SSD). In some embodiments, the semiconductor memory device 102 is a flash drive (e.g., a USB flash drive). In some embodiments, the memory device 102 is a non-volatile memory device. In some embodiments, the semiconductor memory device 102 is a flash memory device. In some embodiments, the semiconductor memory device 102 is a NAND flash memory device. The memory device 102 may generally be configured to store data thereon. In some embodiments, the data stored thereon may be of a confidential or sensitive nature, for which data compromises may not be desired. In some embodiments, the memory device 102 is included in a mobile system 106 that is intended to be transported or is generally mobile. The mobile system 106 and/or memory device 102 may be movable relative to the host device 104 such that the memory device 102 may be moved away from the host device 104. In some embodiments, unintended and/or unauthorized movement of the memory device 102 away from the host device 104 may cause the memory device 102 to initiate a procedure for preventing access to data stored thereon, for example, a self-erasing procedure for erasing or overwriting data stored thereon, as discussed in more detail below.

In some embodiments, the memory device 102 is included as a component or part of a mobile system 106, which may be a device, system or generally an article of manufacture that includes the memory device 102. In some embodiments, the mobile system 106 is configured to be generally mobile, portable or otherwise transportable. For example, the mobile system 106 may be, but is not limited to, a laptop, a smart phone, a tablet, a portable storage device (e.g., a USB flash drive), a manned vehicle (e.g., aircraft, automobile, train), or an unmanned vehicle (e.g., an unmanned aerial vehicle (UAV)). In some embodiments, the memory device 102 is coupled to the mobile system 106 such that the memory device 102 moves with the mobile system 106. For example, in an instance where the mobile system 106 is a UAV, the semiconductor memory device 102 is housed within an outer casing thereof such that the memory device 102 remains generally fixed to the UAV while it is in use. As a further example, the mobile system 106 may be a USB flash drive including the semiconductor memory device 102.

In some embodiments, the semiconductor memory device 102 is configured to be easily removed from the mobile system 106. For example, the semiconductor memory device 102 may be coupled to a housing or casing of the mobile system 106 via a modular configuration that allows for easy attachment and removal therefrom. In other embodiments, the semiconductor memory device 102 is coupled to the housing of the mobile system 106 such that detachment of the memory device 102 therefrom requires at least partial disassembly of the housing.

The memory device 102 may include a memory die 108a for storing data thereon. The memory die 108a may generally be storage means configured to store an amount of electrical charge (e.g., provide a data storage amount). In some embodiments, the memory device 102 includes a plurality of memory dies 108a-108n each configured to store data thereon. The memory dies 108a-108n may be generally the same as one another. In some embodiments, one or more of the memory dies 108a-108n may be memory chips comprising two or more memory dies each. The number of memory dies 108a-108n included in the semiconductor memory device 102 is not necessarily limited to the two illustrated in FIG. 1. In some embodiments, the memory dies 108a-108n are non-volatile memory dies, such as, but not limited to, NAND flash memory dies. The memory dies 108a-108n may include an array of memory cells for storing bits of data thereon as an electrical charge.

The semiconductor memory device 102 may include a memory controller 110 in communication with the memory dies 108a-108n and configured to store, retrieve and/or manage data stored thereon. The controller 110 may generally be control means for controlling access to and/or operation of the memory dies 108a-108n. The controller 110 may be configured to control the routing of signals (e.g., power, ground, IO signals) to and from the memory dies 108a-108n. In some embodiments, the controller 110 may be an application-specific integrated circuit (ASIC), or any other type of controller. The memory controller 110 may be electrically connected to the memory dies 108a-108n. The memory controller 110 may be electrically connected to the memory dies 108a-108n via a BUS 112 (e.g., a NAND BUS) that provides communication pathways between the memory dies 108a-108n and memory controller 110. In some embodiments, the BUS 112 includes a set of physical wires or traces on a substrate between the memory dies 108a-108n and memory controller 110. In some embodiments, the semiconductor memory device 102 includes a substrate (not shown) that acts as a mechanical base support for the memory device 102.

The memory controller 110 may be configured to prevent access to data stored on the memory die(s) 108a-108n based on a determination of whether the semiconductor memory device 102 is connected to the host device 104. Connection of the semiconductor memory device 102 with the host device 104 may be defined by, for example, one or more of: an electrical connection, a physical connection (e.g., a wired connection), a wireless connection (e.g., Wi-Fi, Bluetooth™, near field communication (NFC)), and/or a cloud-based connection (e.g., virtual private network (VPN), web services). In some instances, connection of the semiconductor memory device 102 with the host device 104 is defined at least partially by a physical and electrical connection that allows for the transfer of power and/or data therebetween. For example, when connected, the semiconductor memory device 102 and host device 104 are physically and electrically coupled via a cable or the like. The memory controller 110 may be configured to determine if there is a physical and/or electrical connection between the memory device 102 and host device 104.

In some embodiments, connection of the semiconductor memory device 102 with the host device 104 may be defined at least partially by a proximity of the semiconductor memory device 102 to the host device 104. The memory controller 110 may be configured to determine whether the memory device 102 is connected to the host device 104 based on the proximity of the memory device 102 to the host device 104. In some embodiments, the memory controller 110 is configured to determine the distance from the memory device 102 and/or mobile system 106 to the host device 104 based on a geographical location of the memory device 102 and/or mobile system 106 and a geographical location of the host device 104 (e.g., via global positioning system). For sake of brevity, distance of the memory device 102 and/or mobile system 106 from the host device 104 will be described in relation to the memory device 102 and host device 104. However, it should be understood that the distance of the memory device 102 from the host device 104 may also represent the distance of the mobile system 106 from the host device 104.

In some embodiments, the memory controller 110 is configured to determine if the memory device 102 is connected to the host device 104 based on a signal strength between the memory device 102 and host device 104. For example, the controller 110 is configured to execute a Bluetooth™ low energy (BLE) based proximity detection and/or a Wi-Fi based proximity detection to determine the signal strength between the memory device 102 and host device 104 and approximate a distance therebetween. The memory controller 110 may be configured to execute other methods of proximity detection, such as, but not limited to: time of flight (ToF), near field communications (NFC), proximity sensing (e.g., via infrared sensors), radio frequency identification (RFID), ultrasonic sensing, magnetic field detection sensing, and/or vision based sensing.

In some embodiments, the memory controller 110 is configured to determine if the memory device 102 is connected to a known host device 104. A known host device 104 may be a host device 104 that is authorized for use with the memory device 102 and/or recognized by the memory device 102 (e.g., for security and/or configuration purposes). In some embodiments, a known host device 104 may be a host device 104 that the memory device 102 was previously connected to. The controller 110 may be configured to determine if a known host device 104 is connected to the memory device 102 via a unique identifier of the host device 104. Protocols such as, but not limited to, NVMe and USB may allow for the memory controller 110 to identify a unique ID (e.g., serial number) of the host device 104. The memory controller 110 may be configured to compare a unique identifier of the host device 104 to a list of known host device identifiers stored on the memory device 102 to determine whether the connected host device 104 is a known host or not.

In some embodiments, the memory controller 110 is configured to determine if a connected host device 104 is a known host device based on the behavior of the host device 104. For example, the memory controller 110 is configured to detect and compare sequences of commands and/or other operations executed at the host device 104 to a set of known operations stored on the memory device 102 to determine whether the host device 104 is a known host device. In some embodiments, the memory controller 110 is configured to determine whether a host device 104 is a known host device via an authentication protocol. For example, the controller 110 is configured to execute a challenge-response protocol (e.g., via UFS with RPMB or NVMe with security commands) with the host device 104 to determine if the host device 104 is a known host device.

In some embodiments, a known host device 104 is configured to execute a host-device pairing sequence on first connection to the memory device 102. A known host device 104 may be configured to, on first connection of the memory device 102, execute a pairing process (e.g., secure provisioning) causing the memory device 102 to store a security key or token thereon, which may be used as proof of authentication between the host device 104 and memory device 102 at a later time. For example, the memory controller 110 may be configured to authenticate a host device 104 as a known host based on whether the host device 104 is able to meet a criteria (e.g., proving knowledge of) the security key or token stored on the memory device 102. In some embodiments, the host device 104 is configured to send an identifier to the memory device 102 during enumeration. The memory device 102, via memory controller 110, may be configured to receive the identifier and determine, based on the identifier, whether the host device 104 is a known host device.

The memory controller 110 may be configured to determine whether the host device 104 and memory device 102 are connected via one or more of the criteria discussed above and/or other criterion that may be specific to the intended use of the memory device 102. The criterion discussed above may relate to instances where the memory device 102 is intended to be transported to a geographical location and/or is intended to be deployed into an environment in which it may fall into the possession of unauthorized individuals. Connection with the host device 104 may be representative that the memory device 102 has arrived at an intended destination rather than an unintended one. In some embodiments, loss of a connection between the memory device 102 and host device 104 may indicate that memory device 102 is at greater risk of being in possession of unauthorized individuals. In the event that the memory device 102 does not arrive at an intended destination, the memory controller 110 may be configured to ensure that the data stored thereon is not exposed or compromised.

In some embodiments, the memory controller 110 is configured to prevent a set of data stored on the memory dies 108a-108n from being accessed or modified in the event that the memory device 102 is not connected to the host device 104 within a predetermined amount of time. The memory controller 110 may be configured to detect disconnection of the semiconductor memory device 102 from the host device 104. Disconnection of the semiconductor memory device 102 from host device 104 may cause the memory controller 110 to initiate a timer to track the amount of time that the memory device 102 has been disconnected from the host device 104 according to some embodiments. The timer may be configured, for example, to count down from a predetermined timeout value. The memory controller 110 may be configured to enable a user to set the timeout value. For example, when connected to the host device 104 a user may input the timeout value via a corresponding graphical user interface (GUI). The timeout value may be representative of an expected amount time for which the memory device 102 will be disconnected from the host device 104. For example, in an instance where the memory device 102 is housed within a UAV for military use, the timeout value may be set to correspond to an expected mission length prior to the UAV being deployed on mission. In another instance, the memory device 102 is housed within a laptop computer used to collect medical information off-site from a medical facility where the host device 104 is located. In such instances, the timeout value may be set based on an expected amount of time the laptop computer will be located off-site.

The memory controller 110 may be configured to, in response to determining that the amount of time the memory device 102 has been disconnected from the host device 104 is greater than or equal to the timeout value, prevent the data stored on the memory die(s) 108a-108n from being accessed or modified. For example, in response to the timeout value being reached, the memory controller 110 causes data stored on the memory dies 108a-108a to be erased, locked or rendered otherwise inaccessible. In some embodiments, preventing the set of data stored on the memory die(s) 108a-108n from being accessed or modified via the memory controller 110 includes one or more of: 1) preventing any read or write comments being sent to the memory die(s) 108a-108n; 2) erasing encryption keys associated with the set of data stored on the memory die(s) 108a-108n; 3) deleting a logical to physical (L2P) table associated with the set of data stored on the memory die(s) 108a-108n; and 4) transmitting an erase command to the memory die(s) 108a-108n to cause the set of data stored thereon to be erased or overwritten. In some embodiments, executing items 1), 2), or 3) may allow the data to remain on memory die(s) 108a-108n, and therefore possibly retrievable if memory device 102 is recovered. On the other hand, item 4) may be configured to permanently remove or overwrite the data on memory die(s) 108a-108n such that the data will not be recoverable under any circumstances.

In some embodiments, the memory controller 110 is configured to execute each of items 1)-4) in the preceding paragraph when preventing the set of data stored on the memory die(s) 108a-108n from being accessed or modified. In some embodiments, the memory controller 110 is configured to execute each of items 2)-4) in the preceding paragraph when preventing the set of data stored on the memory die(s) 108a-108n from being accessed or modified. In some embodiments, the memory controller 110 is configured to execute each of items 2)-4) in a sequential order according to a predetermined criteria of the set of data stored on the memory die(s) 108a-108n. The predetermined criteria of the set of data may correspond to the sensitivity and/or confidentiality of the data. In some embodiments, the memory controller 110 is configured to enable a user to set the predetermined criteria. In some embodiments, the memory controller 110 is configured to enable a user to select which of the above items 1)-4) in the preceding paragraph the memory controller 110 is configured to execute when preventing data on the memory dies 108a-108n from being accessed.

In some embodiments, the memory controller 110 is configured to alter the execution sequence of items 1)-4) based on one or more of: a number of failed authentication attempts, a trigger event from a host device 104 and sensitivity classification of data stored on the memory device 102. In some embodiments, the memory controller 110 is configured to alter the execution sequence of one or more of items 1)-4) above in response to a number of failed authentication attempts between the memory device 102 and a host device 104. In some embodiments, the memory controller 110 is configured to receive, from a host device 104, a trigger event such as, but not limited to, a sanitize request, a secure erase request and alter the execution sequence of items 1)-4) based on the trigger event. In some embodiments, the memory controller 110 is configured to alter the execution sequence of one or more of items 1)-4) in response to detecting that data regions containing data marked as sensitive on the memory device 102 are requested to be accessed by an unauthorized device.

In some embodiments, the memory controller 110 is configured to prevent the set of data stored on the memory die(s) 108a-108n from being accessed or modified in response to detecting that the semiconductor memory device 102 is connected to a device other than a trusted device (e.g., the host device 104). Trusted devices may include the host device 104 and the device that the memory device 102 is included in (e.g., the mobile system 106). For example, in the instance where the memory device 102 is included in a UAV, the UAV and the host device 104 may be recognized by the memory controller 110 as trusted devices. In some embodiments, the memory controller 110 is configured to determine if a connected device is trusted in response to receiving a read and/or write command being sent to the memory device 102. The memory controller 110 may be configured to validate, or authenticate, the connection between the connected device and memory device 102 to determine if the connected device is a known host device as discussed above. In some embodiments, the memory controller 110 detects the physical and/or electrical connection of the memory device 102 to another device via a connection detection process specific to the type of interface used. Some non-limiting examples of interface types supported by the memory device 102 may include, but are not limited to, PCIe, USB, and UFS.

In some embodiments, the memory controller 110 is configured to determine if the memory device 102 is connected to the host device 104 and reset and pause the timer tracking the amount of time the memory device 102 has been disconnected from the host device 104. The memory controller 110 may be configured to validate that the host device 104 is a known or trusted device and in response to the memory device 102 being connected thereto, reset and pause the timer. Resetting and pausing the timer may prevent the memory controller 110 from preventing access to the data stored on the memory dies 108a-108n. For example, resetting and pausing the timer via memory controller 110 prevents the memory controller 110 from initiating erasure of the memory dies 108a-108n. In some embodiments, there may be more than one host device 104 that the memory controller 110 is configured to validate as a known host device as discussed above.

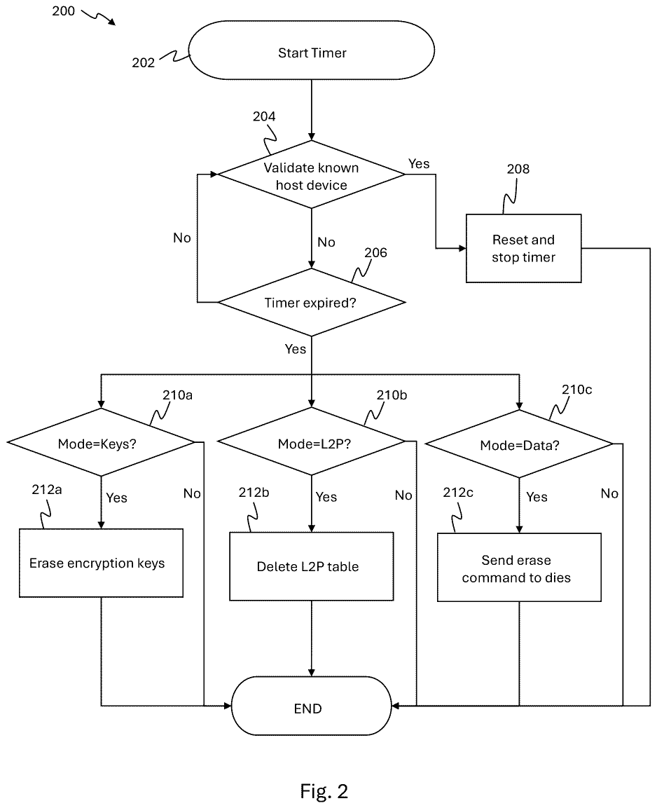

Referring to FIG. 2, there is shown a flowchart illustrating a method, generally designated 200, of automatically erasing a semiconductor memory device in accordance with an exemplary embodiment of the present disclosure. In some embodiments, the method 200 may be carried out via system 100. Prior to the method 200 a semiconductor memory device (e.g., memory device 102) may be connected to a host device (e.g., host device 104). In some embodiments, prior the method 200 the memory device 102 is connected to the host device 104 via a direct connection (e.g., a point-to-point link) or an indirect connection (e.g., connection through intermediate components). The method 200 may include the step 202 of starting a timer. For example, in response to detecting the disconnection of the memory device 102 from the host device 104 the memory controller 110 is configured to initiate the timer based on a timeout value, which may be set by a user as discussed above.

The method 200 may include the step 204 of validating a known host device. For example, the memory controller 110 may be configured to determine, while the timer is active, whether the memory device 102 is connected to a known (e.g., authorized) host device 104. If the memory device is not connected to a known host device 104 at step 204, the method 200 may proceed to the step 206 of determining if the timer has expired. For example, the memory controller 110 is configured to determine that the memory device 102 is not connected to host device 104 and whether the timer has expired. If the memory device 102 is connected to a known host device 104 at step 204, the method 200 may proceed to the step 208 of resetting and stopping the timer. For example, the memory controller 110 is configured to validate a connection between host device 104 and memory device 102 and reset and stop the timer as discussed above. In such instances, the method 200 terminates.

Returning to step 206, if the timer has not expired the method 200 may return to the step 204 and loop until either the timer has expired or the memory device is connected to a known host device 104. For example, the memory controller 110 is configured to continue the timer until either the memory device 102 is connected to the host device 104 or the timer expires. The memory controller 110 may be configured to continuously perform the loop between steps 204 and 206 until one of the two criteria is met.

If at step 206 the timer has expired, the method 200 proceeds to steps 210a-210c to prevent data stored on the memory device from being accessed. In some embodiments, steps 210a-210c are performed generally simultaneously or, in other embodiments, according to a sequential order. Steps 210a-210c may generally relate to determining the manner with which data stored on the memory device is prevented from being accessed and/or modified. Step 210a may correspond to determining if encryption keys are to be erased. Step 210b may correspond to determining if an L2P table is to be deleted. Step 210c may correspond to determining if an erase command is intended to be sent to the memory dies of the memory device. As discussed above, the memory controller 110 may be configured to enable a user to select what types or modes of data erasure/deletion are to be executed by the memory controller. In some embodiments, only one of steps 210a-210c occurs. In some embodiments, two of steps 210a-210c occur. In still further embodiments, all three steps 210a-210c occur. The user may select which of steps 210a-210c occurs based on, for example, the type of data stored in memory device 102. For example, a user may select all three steps 210a-210c when highly sensitive data is stored in memory device 102.

If at steps 210a-210c, it is determined that the corresponding form of data erasure is selected, the method 200 may proceed to the respective steps 212a-212c that correspond to the data erasure actions. For example, if at step 210a the memory controller 110 determines that encryption key erasure is selected, the memory controller 110 is configured to cause all, or at least a portion, of the encryption keys associated with the data stored on the memory dies 108a-108n to be erased. If at step 210b the memory controller 110 determines that L2P deletion is selected, the memory controller 110 is configured to cause an L2P table associated with the data stored on the memory dies 108a-108n to be erased. If at step 210c the memory controller 110 determines that data erasure is selected, the memory controller 110 is configured to cause the data stored on the memory dies 108 a-108n to be erased (e.g., the values of floating gate transistors all set to a 0 bit or 1 bit charge value).

If at one or more of steps 210a-210c it is determined that the corresponding form of data erasure is not selected, the method 200 may proceed with the remaining steps 210a-210c which are selected. For example, a user may select to erase all encryption keys and the L2P table and not send an erase command to the memory dies 108a-108n. Accordingly, the memory controller 110 is configured to execute steps 212a-212b and not step 212c. It should be understood that the memory controller 110 may be configured to execute any number of steps 212a-212c in any sequential order as defined by, in some instances, a user selection of the erasure procedures and order thereof. The method 200 may terminate following steps 210a-210c and/or the corresponding steps 212a-212c. In some embodiments, as noted above, the data erasure may occur in a defined sequence. For example, encryption keys may be erased first (212a), followed by deletion of the L2P table (212b), and finally sending an erase command to the memory dies to erase all data from the memory dies (212c). The time between each of these actions may be variable and set by the user. In some embodiments, there may be an intentional delay or separate timer before sending an erase command (212c) occurs. This could, for example, provide some time for recovering memory device 102 before the data is permanently erased from the memory dies.

It will be appreciated by those skilled in the art that changes could be made to the exemplary embodiments shown and described above without departing from the broad inventive concepts thereof. It is understood, therefore, that this invention is not limited to the exemplary embodiments shown and described, but it is intended to cover modifications within the spirit and scope of the present invention as defined by the claims. For example, specific features of the exemplary embodiments may or may not be part of the claimed invention and various features of the disclosed embodiments may be combined. The words “right”, “left”, “lower” and “upper” designate directions in the drawings to which reference is made. Unless specifically set forth herein, the terms “a”, “an” and “the” are not limited to one element but instead should be read as meaning “at least one”. As used herein, the term “about” may refer to +/−10% of the value referenced. For example, “about 9” is understood to encompass 8.1 and 9.9.

It is to be understood that at least some of the figures and descriptions of the invention have been simplified to focus on elements that are relevant for a clear understanding of the invention, while eliminating, for purposes of clarity, other elements that those of ordinary skill in the art will appreciate may also comprise a portion of the invention. However, because such elements are well known in the art, and because they do not necessarily facilitate a better understanding of the invention, a description of such elements is not provided herein.

Further, to the extent that the methods of the present invention do not rely on the particular order of steps set forth herein, the particular order of the steps should not be construed as limitation on the claims. Any claims directed to the methods of the present invention should not be limited to the performance of their steps in the order written, and one skilled in the art can readily appreciate that the steps may be varied and still remain within the spirit and scope of the present invention.

What is claimed is:

1. A semiconductor memory device comprising:
a memory die having stored thereon a set of data; and
a memory controller electrically connected to the memory die, the memory controller configured to:
detect disconnection of the semiconductor memory device from a host device;
determine an amount of time that the semiconductor memory device has been disconnected from the host device; and
in response to determining that the amount of time is greater than or equal to a timeout value, prevent the set of data stored on the memory die from being accessed or modified.

2. The semiconductor memory device of claim 1, wherein the memory controller is further configured to:
in response to detecting the removal of the semiconductor memory device from the host device, initiate a timer to track the amount of time that the semiconductor memory device has been disconnected from the host device.

3. The semiconductor memory device of claim 2, wherein the memory controller is further configured to:
determine if the semiconductor memory device is connected to the host device; and
reset and pause the timer tracking the amount of time that the semiconductor memory device has been disconnected from the host device.

4. The semiconductor memory device of claim 1, wherein the memory controller is further configured to, when preventing the set of data stored on the memory die from being accessed or modified, prevent any read or write commands to the memory die.

5. The semiconductor memory device of claim 1, wherein the memory controller is further configured to, when preventing the set of data stored on the memory die from being accessed or modified, erase encryption keys associated with the set of data stored on the memory die.

6. The semiconductor memory device of claim 1, wherein the memory controller is further configured to, when preventing the set of data stored on the memory die from being accessed or modified, delete a logical to physical (L2P) table associated with the set of data stored on the memory die.

7. The semiconductor memory device of claim 1, wherein the memory controller is further configured to, when preventing the set of data stored on the memory die from being accessed or modified, transmit an erase command to the memory die to cause the set of data stored thereon to be erased.

8. The semiconductor memory device of claim 1, wherein the memory controller is further configured to, when preventing the set of data stored on the memory die from being accessed or modified, execute one or more of:
erasure of encryption keys associated with the set of data stored on the memory die;
deletion of a logical to physical (L2P) table associated with the set of data stored on the memory die; and
transmission of an erase command to the memory die to cause the set of data stored thereon to be erased.

9. The semiconductor memory device of claim 8, wherein the memory controller is further configured to execute the erasure of the encryption keys, deletion of the L2P table and transmission of the erase command in a sequence according to predetermined criteria of the set of data stored on the memory die.

10. The semiconductor memory device of claim 9, wherein the memory controller is configured to enable a user to set the predetermined criteria.

11. The semiconductor memory device of claim 1, wherein the memory controller is further configured to:
detect that the semiconductor memory device is connected to an external device other than the host device; and
prevent the set of data stored on the memory die from being accessed or modified.

12. The semiconductor memory device of claim 1, wherein the memory die is a NAND flash memory die.

13. A method of preventing access or modification of data stored on a semiconductor memory device, the method comprising:
at a memory controller electrically connected to a memory die:
detecting disconnection of the semiconductor memory device from a host device;
determining an amount of time that the semiconductor memory device has been disconnected from the host device; and
in response to determining that the amount of time is greater than or equal to a timeout value, preventing a set of data stored on the memory die from being accessed or modified.

14. The method of claim 13 further comprising, at the memory controller:
in response to detecting the removal of the semiconductor memory device from the host device, initiating a timer to track the amount of time that the semiconductor memory device has been disconnected from the host device.

15. The method of claim 14 further comprising, at the memory controller:
determining if the semiconductor memory device is connected to the host device; and
resetting and pausing the timer tracking the amount of time that the semiconductor memory device has been disconnected from the host device.

16. The method of claim 13, wherein preventing the set of data stored on the memory die from being accessed or modified includes erasing, via the memory controller, encryption keys associated with the set of data stored on the memory die.

17. The method of claim 13, wherein preventing the set of data stored on the memory die from being accessed or modified includes deleting, via the memory controller, a logical to physical (L2P) table associated with the set of data stored on the memory die.

18. The method of claim 13, wherein preventing the set of data stored on the memory die from being accessed or modified includes, via the memory controller, transmitting an erase command to the memory die to cause the set of data stored thereon to be erased.

19. The method of claim 13, preventing the set of data stored on the memory die from being accessed or modified includes executing, via the memory controller, one or more of:
erasing encryption keys associated with the set of data stored on the memory die;
deleting a logical to physical (L2P) table associated with the set of data stored on the memory die; and
transmitting an erase command to the memory die to cause the set of data stored thereon to be erased.

20. A semiconductor memory device comprising:
a storage means for storing a set of data; and
a storage controller means for controlling access to the storage means, the storage controller means configured to:
detect disconnection of the semiconductor memory device from a host device;
determine an amount of time that the semiconductor memory device has been disconnected from the host device; and
in response to determining that the amount of time is greater than or equal to a timeout value, prevent the set of data stored on the storage means from being accessed or modified.
